(19) United States
(12) Patent Application Publication
(10) Pub. No.: US 2025/0306132 A1
(43) Pub. Date: Oct. 2, 2025

(54) ENHANCED SMART CABLE AND FIBER FOR DETECTING DISCONNECTIONS AND OTHER SIGNAL CHANGES

(71) Applicant: CenturyLink Intellectual Property LLC, Denver, CO (US)

(72) Inventor: Asghar HUSSAIN, McLean, VA (US)

(73) Assignee: CenturyLink Intellectual Property LLC, Denver, CO (US)

(21) Appl. No.: 19/085,622

(22) Filed: Mar. 20, 2025

Related U.S. Application Data
(60) Provisional application No. 63/570,715, filed on Mar. 27, 2024.

(51) Int. Cl. G01R 31/66; H04L 41/50

(52) U.S. Cl. CPC G01R 31/66; H04L 41/50

(57) ABSTRACT

This disclosure describes smart wires with sensors and communications circuitry for monitoring the status of the smart wires. The smart wires may include one or more sensors configured to detect whether the smart wire is connected to or disconnected from a device or port; and communications circuitry configured to wirelessly communicate data, to a management network, indicative of whether the smart wire is connected to or disconnected from the device or port, wherein the management network is unassociated with a service using the smart wire and the device or port.

### CROSS-REFERENCE TO RELATED APPLICATIONS

This application claims the benefit of priority from U.S. Provisional Application Ser. No. 63/570,715, filed Mar. 27, 2024, which is incorporated herein by reference in its entirety.

### TECHNICAL FIELD

Embodiments of the present technology generally relate to network cables and fibers, in particular, network cables and fibers with detection capabilities.

### BACKGROUND

Some telecommunications networks, in labs and data centers, use a variety of cables and fibers to connect communications devices for testing and providing services to users of the networks. Network cables and fibers often become disconnected and experience signal changes. To detect network cable and fiber disconnections and signal changes, data of the cables and fibers may be sent to remote traffic analyzers for analysis via a separate interface module.

### SUMMARY

According to some embodiments, a smart wire may include: one or more sensors configured to detect whether the smart wire is connected to or disconnected from a device or port; and communications circuitry configured to wirelessly communicate data, to a management network, indicative of whether the smart wire is connected to or disconnected from the device or port, wherein the management network is unassociated with a service using the smart wire and the device or port.

According to some embodiments, a smart wire may include: one or more sensors configured to detect a status of the smart wire; and communications circuitry configured to wirelessly communicate data indicative of the status to a management network when the smart wire is disconnected, wherein the management network is unassociated with a service using the smart wire.

According to some embodiments, a smart wire for providing management services for a telecommunications network may include: one or more sensors configured to detect a status of the smart wire; and communications circuitry configured to wirelessly communicate data indicative of the status to a management network when the smart wire is disconnected, wherein the management network is unassociated with a service using the smart wire.

### BRIEF DESCRIPTION OF THE DRAWINGS

The features, and advantages of the disclosure will be apparent from the following description of embodiments as illustrated in the accompanying drawings, in which reference characters refer to the same parts throughout the various views. The drawings are not necessarily to scale, emphasis instead being placed upon illustrating principles of the disclosure:

FIG. 1 illustrates example systems for monitoring a cable/fiber, in accordance with one embodiment of the present disclosure;

FIG. 2 illustrates an example system for monitoring a smart cable/fiber, in accordance with one embodiment of the present disclosure; and

FIG. 3 shows a functional diagram of exemplary smart wire hardware, in accordance with one or more example embodiments of the present disclosure.

### DETAILED DESCRIPTION

The present disclosure will now be described more fully hereinafter with reference to the accompanying drawings, which form a part hereof, and which show, by way of non-limiting illustration, certain example embodiments. Subject matter may, however, be embodied in a variety of different forms and, therefore, covered or claimed subject matter is intended to be construed as not being limited to any example embodiments set forth herein; example embodiments are provided merely to be illustrative. Likewise, a reasonably broad scope for claimed or covered subject matter is intended. Among other things, for example, subject matter may be embodied as methods, devices, components, or systems. Accordingly, embodiments may, for example, take the form of hardware, software, firmware or any combination thereof (other than software per se). The following detailed description is, therefore, not intended to be taken in a limiting sense.

Throughout the specification and claims, terms may have nuanced meanings suggested or implied in context beyond an explicitly stated meaning. Likewise, the phrase “in one embodiment” as used herein does not necessarily refer to the same embodiment and the phrase “in another embodiment” as used herein does not necessarily refer to a different embodiment. It is intended, for example, that claimed subject matter include combinations of example embodiments in whole or in part.

In general, terminology may be understood at least in part from usage in context. For example, terms, such as “and”, “or”, or “and/or,” as used herein may include a variety of meanings that may depend at least in part upon the context in which such terms are used. Typically, “or” if used to associate a list, such as A, B or C, is intended to mean A, B, and C, here used in the inclusive sense, as well as A, B or C, here used in the exclusive sense. In addition, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

The present disclosure is described below with reference to block diagrams and operational illustrations of methods and devices. It is understood that each block of the block diagrams or operational illustrations, and combinations of blocks in the block diagrams or operational illustrations, can be implemented by means of analog or digital hardware and computer program instructions. These computer program instructions can be provided to a processor of a general purpose computer to alter its function as detailed herein, a special purpose computer, ASIC, or other programmable data processing apparatus, such that the instructions, which execute via the processor of the computer or other programmable data processing apparatus, implement the functions/acts specified in the block diagrams or operational block or blocks. In some alternate implementations, the functions/acts noted in the blocks can occur out of the order noted in the operational illustrations. For example, two blocks shown in succession can in fact be executed substantially concurrently or the blocks can sometimes be executed in the reverse order, depending upon the functionality/acts involved.

For the purposes of this disclosure a non-transitory computer readable medium (or computer-readable storage medium/media) stores computer data, which data can include computer program code (or computer-executable instructions) that is executable by a computer, in machine readable form. By way of example, and not limitation, a computer readable medium may include computer readable storage media, for tangible or fixed storage of data, or communication media for transient interpretation of code-containing signals. Computer readable storage media, as used herein, refers to physical or tangible storage (as opposed to signals) and includes without limitation volatile and non-volatile, removable and non-removable media implemented in any method or technology for the tangible storage of information such as computer-readable instructions, data structures, program modules or other data. Computer readable storage media includes, but is not limited to, RAM, ROM, EPROM, EEPROM, flash memory or other solid state memory technology, optical storage, cloud storage, magnetic storage devices, or any other physical or material medium which can be used to tangibly store the desired information or data or instructions and which can be accessed by a computer or processor.

For the purposes of this disclosure the term “server” should be understood to refer to a service point which provides processing, database, and communication facilities. By way of example, and not limitation, the term “server” can refer to a single, physical processor with associated communications and data storage and database facilities, or it can refer to a networked or clustered complex of processors and associated network and storage devices, as well as operating software and one or more database systems and application software that support the services provided by the server. Cloud servers are examples.

For the purposes of this disclosure a “network” should be understood to refer to a network that may couple devices so that communications may be exchanged, such as between a server and a client device or other types of devices, including between wireless devices coupled via a wireless network, for example. A network may also include mass storage, such as network attached storage (NAS), a storage area network (SAN), a content delivery network (CDN) or other forms of computer or machine-readable media, for example. A network may include the Internet, one or more local area networks (LANs), one or more wide area networks (WANs), wire-line type connections, wireless type connections, cellular or any combination thereof. Likewise, sub-networks, which may employ differing architectures or may be compliant or compatible with differing protocols, may interoperate within a larger network.

For purposes of this disclosure, a “wireless network” should be understood to couple client devices with a network. A wireless network may employ stand-alone ad-hoc networks, mesh networks, Wireless LAN (WLAN) networks, cellular networks, or the like. A wireless network may further employ a plurality of network access technologies, including Wi-Fi, Long Term Evolution (LTE), WLAN, Wireless Router mesh, or 2nd, 3rd, 4^{th} or 5^{th} generation (2G, 3G, 4G or 5G) cellular technology, mobile edge computing (MEC), Bluetooth, 802.11b/g/n, or the like. Network access technologies may enable wide area coverage for devices, such as client devices with varying degrees of mobility, for example.

In short, a wireless network may include virtually any type of wireless communication mechanism by which signals may be communicated between devices, such as a client device or a computing device, between or within a network, or the like.

A computing device may be capable of sending or receiving signals, such as via a wired or wireless network, or may be capable of processing or storing signals, such as in memory as physical memory states, and may, therefore, operate as a server. Thus, devices capable of operating as a server may include, as examples, dedicated rack-mounted servers, desktop computers, laptop computers, set top boxes, integrated devices combining various features, such as two or more features of the foregoing devices, or the like.

For purposes of this disclosure, a client (or user, entity, subscriber or customer) device may include a computing device capable of sending or receiving signals, such as via a wired or a wireless network. A client device may, for example, include a desktop computer or a portable device, such as a cellular telephone, a smart phone, a display pager, a radio frequency (RF) device, an infrared (IR) device a Near Field Communication (NFC) device, a Personal Digital Assistant (PDA), a handheld computer, a tablet computer, a phablet, a laptop computer, a set top box, a wearable computer, smart watch, an integrated or distributed device combining various features, such as features of the forgoing devices, or the like.

A client device may vary in terms of capabilities or features. Claimed subject matter is intended to cover a wide range of potential variations, such as a web-enabled client device or previously mentioned devices may include a high-resolution screen (HD or 4K for example), one or more physical or virtual keyboards, mass storage, one or more accelerometers, one or more gyroscopes, global positioning system (GPS) or other location-identifying type capability, or a display with a high degree of functionality, such as a touch-sensitive color 2D or 3D display, for example.

Certain embodiments and principles will be discussed in more detail with reference to the figures. According to some embodiments, as discussed herein, aspects of the present disclosure involve smart cables and fibers, and the like, for detecting disconnections and signal changes.

In telecommunications systems, network cables and fibers wires are used to transmit electrical signals. For example, telecommunications systems may include end user devices such as modems that are typically connected using wires to form a loop with a switch or other telecommunications network equipment that may communicate with the end user devices and a broader network backbone. The network cables and fibers may become disconnected from devices/ports, and/or may experience signal changes (e.g., indicating degradation, damage, etc.).

To detect cable and fiber disconnections and signal changes, the cables and fibers may connect to a small form-factor pluggable (SFP). SFPs are modular interfaces that connect to a transceiver, such as the cables and fibers. The SFPs provide or mirror signal data of the cables and fibers to a remote traffic analyzer, which may receive and analyze the signal data to detect a disconnection or signal change. In this manner, existing techniques for monitoring connection and performance of cables and fibers are dependent on an external device. Alternatively, devices/ports to which cables and fibers connect may detect a disconnection, such as when no data are received from the ports to which the cables and fibers connect.

In addition, some existing devices for detecting when a cable is disconnected or not working rely on their own management connectivity (e.g., a cable/fiber connection). For example, SFPs may use a wired connection to a traffic analyzer, and when the wired connection becomes disconnected or does not work, then the detection and notification cannot occur because the detection and notification are dependent on the wired connection functioning to provide the data to the traffic analyzer.

Other existing techniques use devices to detect signal quality and wire quality, but they are typically larger boxes that use Bluetooth to pair to a phone and rather than something that can be attached to wires and kept there permanently for monitoring.

In one or more embodiments, smart cables and fibers herein may include one or more sensors and one or more radios in an insert piece of the cables and fibers or in the cables and fibers themselves. The one or more sensors may detect signal data of the cables and fibers, including data indicating whether the cables and fibers are connected at each end or disconnected. The one or more radios may transmit signal data (e.g., using Wi-Fi® or the like) to a remote management network that may monitor and store the data. As a result, detecting disconnections and signal changes in the smart cables and fibers herein will not depend on any devices or modules external to the cables or fibers.

In one or more embodiments, the cables or fibers using the smart hardware may be management cables or fibers, and/or cables/fibers connecting to monitoring stations. As a result, their disconnection or performance degradation may still be recognized and reported, in contrast with existing solutions that rely on the management cables to provide cable and fiber data for analysis and to report disconnections or degradation, and/or that rely on connectivity of the monitoring stations themselves.

In one or more embodiments, the sensors may include voltage and/or current sensors (e.g. for Ethernet or other cables). The sensors may include optical sensors to detect light in fiber optics.

In one or more embodiments, the smart cables and fibers herein may be used to communicate data that provides a service. In this manner, the communications provided by the radios (e.g., communications with the management network) would not be part of service provided by the cables and fibers, so the radios would not be providing user services when providing performance data of the cables and fibers to the management network. In contrast, existing cable and fiber monitoring techniques (e.g., using SFPs) rely on the connectivity of the cables and fibers themselves for the communications (e.g., using mirroring or splitting).

In one or more embodiments, the radios of the smart cables and fibers herein may communicate with a network that is not under test or that is not related to the service provided by the cable being monitored. In this manner, the network that communicates with the smart cable/fiber radio may not be dependent on the cable/fiber, so even when the cable/fiber is disconnected or not functioning properly, the radio may still communicate with the network to provide data for the cable/fiber. The radio of the cable or fiber may communicate with the network independent of the connection/disconnection or functioning of the cable or fiber.

In one or more embodiments, the smart communications hardware (the sensor and radio) may be powered by the cable or fiber itself (e.g., when connected to a device) and/or may include a power source (e.g., a CR2 battery or another type of chargeable battery).

In one or more embodiments, to include the smart hardware in the cable or fiber, the cable or fiber may use a splitter or emitter to send traffic along the cable or fiber to the sensor to detect light or voltage/current levels along the cable or fiber.

In one or more embodiments, when the sensor detects a disconnection, abnormality, or change in data (e.g., based on detected data being above or below performance thresholds), the communications circuitry (e.g., radio and communications stack) may provide an indication of the detected data to the remote management network using the wireless network.

The above descriptions are for purposes of illustration and are not meant to be limiting. Numerous other examples, configurations, processes, etc., may exist, some of which are described in greater detail below. Example embodiments will now be described with reference to the accompanying figures.

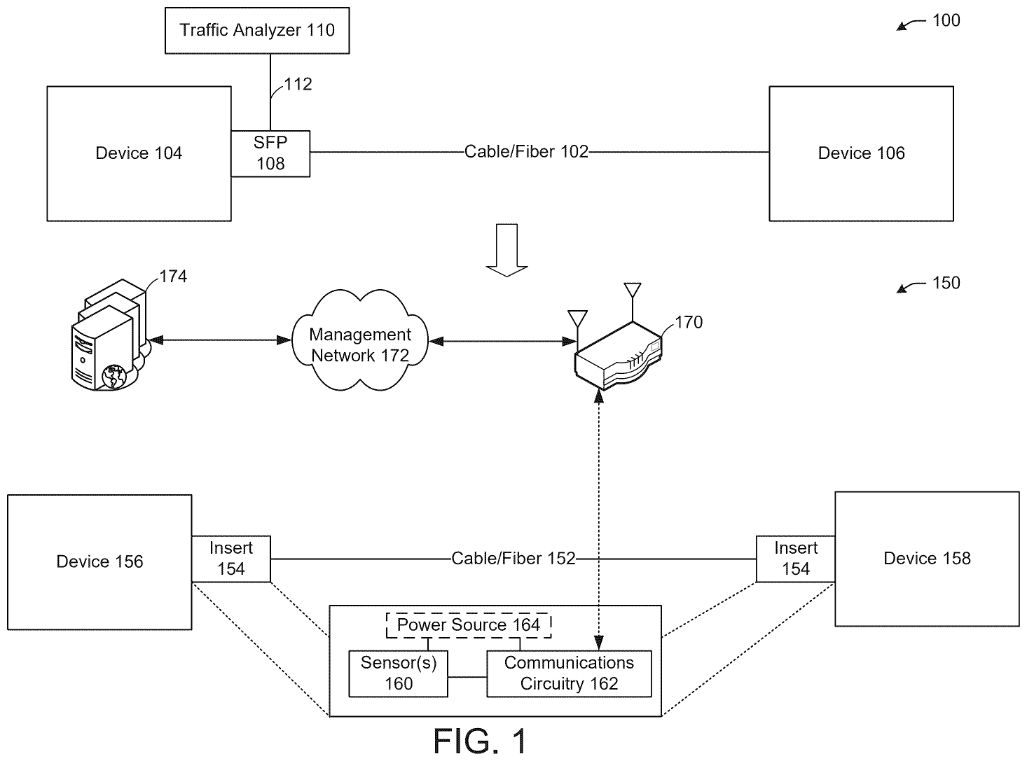

FIG. 1 illustrates example systems for monitoring a cable/fiber, in accordance with one embodiment.

Referring to FIG. 1, a system 100 may include a cable/fiber 102 connected to device 104 on one end and to device 106 on another end. To monitor the cable/fiber 102, a SFP 108 may connect to the cable/fiber 102, and may connect the cable/fiber 102 to the device 104. The SFP 108 may split or mirror traffic from along the cable/fiber 102 to a traffic analyzer 110.

Still referring to FIG. 1, an enhanced system 150 may include a cable/fiber 152 with an insert 154 on each end, connecting to a device 156 and to a device 158 on each end of the cable/fiber 152. The insert 154 may include one or more sensors 160 and communications circuitry 162. Optionally the insert 154 may include a power source 164 (e.g., a battery) to power the sensor 160 and/or the communications circuitry 162). The communications circuitry 162 may communicate wirelessly with a remote access point 170 of a management network 172. The management network 172 may provide the data to a logging/monitoring server 174 to analyze data from the communications circuitry 162 and detect when the cable/fiber 102 is disconnected or experiencing performance changes or degradation. In particular, the communications circuitry 162 may communicate traffic or indications of traffic, along the cable/fiber 102, to the management network 172 for monitoring the status of the cable/fiber 102.

In one or more embodiments, the sensors 160 may include voltage and/or current sensors (e.g. for Ethernet or other cables). The sensors 160 may include optical sensors to detect light in fiber optics.

In one or more embodiments, the insert 154 may include connectors to connect to the device 156 and the device 158. For example, when the cable/fiber 102 is an Ethernet cable connecting to an Ethernet port of the device 156, the insert 154 may include RJ45 connectors. When the cable/fiber 102 is a fiber optic, the insert 154 may include optical fiber connectors.

In one or more embodiments, the cable/fiber 152 may be a management cable/fiber, and/or the device 156 or the device 158 may be monitoring stations. As a result, disconnection or performance degradation of the cable/fiber 152 may still be recognized and reported, in contrast with existing solutions that rely on the management cables to provide cable and fiber data for analysis and to report disconnections or degradation, and/or that rely on connectivity of the monitoring stations themselves.

In one or more embodiments, the cable/fiber 152 may be used to communicate data that provides a service. In this manner, the communications provided by the communications circuitry 162 would not be part of service provided by the cable/fiber 152, so the communications circuitry 162 would not be providing user services when providing performance data of the cable/fiber 152 to the management network 172. In contrast, existing cable and fiber monitoring techniques (e.g., using SFPs) rely on the connectivity of the cables and fibers themselves for the communications (e.g., using mirroring or splitting).

In one or more embodiments, the communications circuitry 162 of the cable/fiber 152 may communicate with a network (e.g., the management network 172) that is not under test or that is not related to the service provided by the cable/fiber 152 being monitored. In this manner, the management network 172 that communicates with the cable/fiber 152 communications circuitry 162 may not be dependent on the cable/fiber 152, so even when the cable/fiber 152 is disconnected or not functioning properly, the communications circuitry 162 may still communicate with the management network 172 to provide data for the cable/fiber 152. The communications circuitry 172 may communicate with the management network 172 independent of the connection/disconnection or functioning of the cable/fiber 152.

In one or more embodiments, when the sensor 160 detects a disconnection, abnormality, or change in data (e.g., based on detected data being above or below performance thresholds), the communications circuitry 162 may provide an indication of the detected data to the remote management network 172.

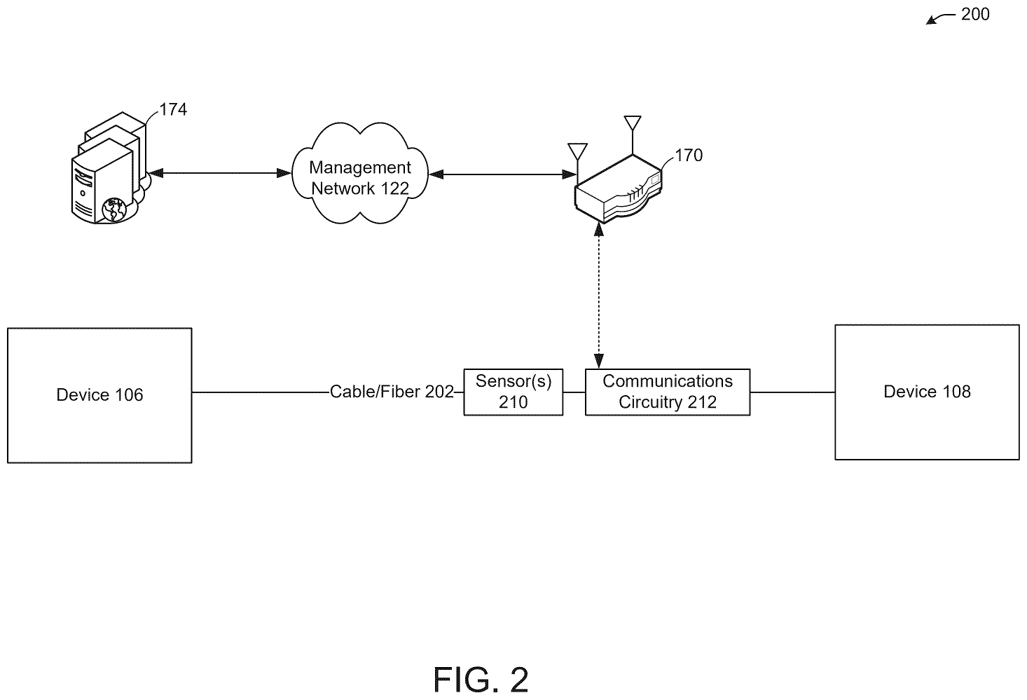

FIG. 2 illustrates an example system 200 for monitoring a smart cable/fiber, in accordance with one embodiment.

Referring to FIG. 2, the system 200 may include a cable/fiber 202 connecting to the device 156 and to device 158 of FIG. 1. In the cable/fiber 102 may be one or more sensors 210 (e.g., like the one or more sensors 160 of FIG. 1) and communications circuitry 212 (e.g., like the communications circuitry 162 of FIG. 1). The communications circuitry 212 may communicate with the management network 172 via the remote access point 170 for monitoring the status of the cable/fiber 202 as described with respect to FIG. 1.

Referring to FIGS. 1 and 2, the cable/fiber 152 and the cable/fiber 202 may be referred to herein as wires for simplicity.

Referring to FIGS. 1 and 2, the management network 172 may have any suitable communication range associated therewith and may include, for example, global networks (e.g., the Internet), metropolitan area networks (MANs), wide area networks (WANs), local area networks (LANs), or personal area networks (PANs). The communications circuitry 162 and 212, and the management network 172, may include one or more communications antennas. The one or more communications antennas may be any suitable type of antennas corresponding to the communications protocols used by the communications circuitry 162 and 212, and the management network 172. Some non-limiting examples of suitable communications antennas include Wi-Fi antennas, Institute of Electrical and Electronics Engineers (IEEE) 802.11 family of standards compatible antennas, directional antennas, non-directional antennas, dipole antennas, folded dipole antennas, patch antennas, multiple-input multiple-output (MIMO) antennas, omnidirectional antennas, quasi-omnidirectional antennas, or the like. The one or more communications antennas may be communicatively coupled to a radio component to transmit and/or receive signals, such as communications signals to and/or from the communications circuitry 162 and 212, and the management network 172.

Any of the user communications circuitry 162 and 212, and the management network 172 may include any suitable radio and/or transceiver for transmitting and/or receiving radio frequency (RF) signals in the bandwidth and/or channels corresponding to the communications protocols utilized by any of the communications circuitry 162 and 212, and the management network 172 to communicate with each other. The radio components may include hardware and/or software to modulate and/or demodulate communications signals according to pre-established transmission protocols. The radio components may further have hardware and/or software instructions to communicate via one or more Wi-Fi and/or Wi-Fi direct protocols, as standardized by the Institute of Electrical and Electronics Engineers (IEEE) 802.11 standards. In certain example embodiments, the radio component, in cooperation with the communications antennas, may be configured to communicate via 2.4 GHz channels (e.g. 802.11b, 802.11g, 802.11n, 802.11ax), 5 GHz channels (e.g. 802.11n, 802.11ac, 802.11ax, 802.11be, etc.), 6 GHz channels (e.g., 802.11ax, 802.11be, etc.), or 60 GHZ channels (e.g. 802.11ad, 802.11ay). 800 MHZ channels (e.g. 802.11ah). The communications antennas may operate at 28 GHz and 40 GHz. It should be understood that this list of communication channels in accordance with certain 802.11 standards is only a partial list and that other 802.11 standards may be used (e.g., Next Generation Wi-Fi, or other standards). In some embodiments, non-Wi-Fi protocols may be used for communications between devices, such as Bluetooth, dedicated short-range communication (DSRC), Ultra-High Frequency (UHF) (e.g. IEEE 802.11af, IEEE 802.22), white band frequency (e.g., white spaces), or other packetized radio communications. The radio component may include any known receiver and baseband suitable for communicating via the communications protocols. The radio component may further include a low noise amplifier (LNA), additional signal amplifiers, an analog-to-digital (A/D) converter, one or more buffers, and digital baseband.

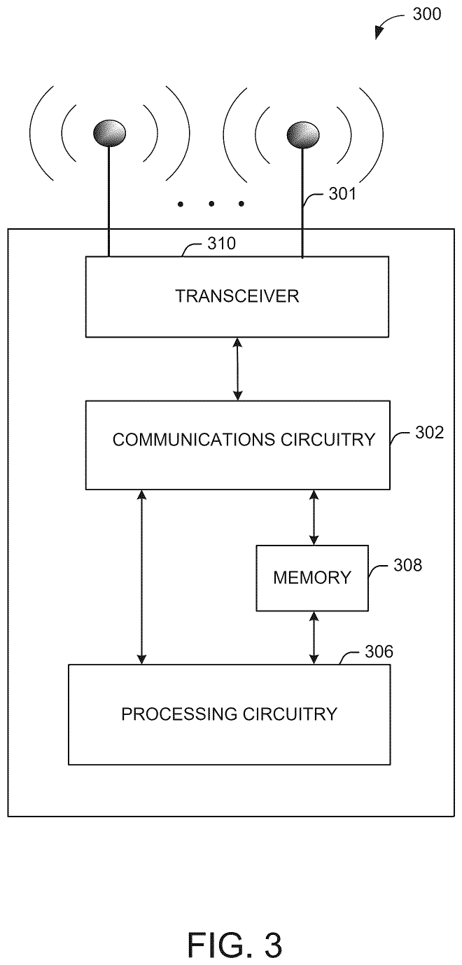

FIG. 3 shows a functional diagram of exemplary smart wire hardware 300, in accordance with one or more example embodiments of the present disclosure. In one embodiment, FIG. 3 illustrates a functional block diagram of hardwire that may be suitable for use in the insert 154 of FIG. 1 and/or the cable/fiber 202 in accordance with some embodiments. The smart wire hardware 300 may also be suitable for use as a handheld device, a mobile device, a cellular telephone, a smartphone, a tablet, a netbook, a wireless terminal, a laptop computer, a wearable computer device, a femtocell, a high data rate (HDR) subscriber station, an access point, an access terminal, or other personal communication system (PCS) device.

The smart wire hardware 300 may include communications circuitry 302 and a transceiver 310 (e.g., representing the communications circuitry 162 or the communications circuitry 212 of FIG. 2 for transmitting and receiving signals to and from the remote access point 170 using one or more antennas 301. The communications circuitry 302 may include circuitry that can operate the physical layer (PHY) communications and/or medium access control (MAC) communications for controlling access to the wireless medium, and/or any other communications layers for transmitting and receiving signals. The smart wire hardware 300 may also include processing circuitry 306 and memory 308 arranged to perform the operations described herein. In some embodiments, the communications circuitry 302 and the processing circuitry 306 may be configured to perform operations detailed in the above figures, diagrams, and flows.

In accordance with some embodiments, the communications circuitry 302 may be arranged to contend for a wireless medium and configure frames or packets for communicating over the wireless medium. The communications circuitry 32 may be arranged to transmit and receive signals. The communications circuitry 302 may also include circuitry for modulation/demodulation, upconversion/downconversion, filtering, amplification, etc. In some embodiments, the processing circuitry 306 of the smart wire hardware 300 may include one or more processors. In other embodiments, two or more antennas 301 may be coupled to the communications circuitry 302 arranged for sending and receiving signals. The memory 308 may store information for configuring the processing circuitry 306 to perform operations for configuring and transmitting message frames and performing the various operations described herein. The memory 308 may include any type of memory, including non-transitory memory, for storing information in a form readable by a machine (e.g., a computer). For example, the memory 308 may include a computer-readable storage device, read-only memory (ROM), random-access memory (RAM), and other storage devices and media.

In some embodiments, the smart wire hardware 300 may be part of a portable wireless communication device, such as a personal digital assistant (PDA), a laptop or portable computer with wireless communication capability, a web tablet, a wireless telephone, a smartphone, a wireless headset, a pager, an instant messaging device, a digital camera, an access point, a television, a medical device (e.g., a heart rate monitor, a blood pressure monitor, etc.), a wearable computer device, or another device that may receive and/or transmit information wirelessly.

In some embodiments, the smart wire hardware 300 may include one or more antennas 301. The antennas 301 may include one or more directional or omnidirectional antennas, including, for example, dipole antennas, monopole antennas, patch antennas, loop antennas, microstrip antennas, or other types of antennas suitable for transmission of RF signals. In some embodiments, instead of two or more antennas, a single antenna with multiple apertures may be used. In these embodiments, each aperture may be considered a separate antenna. In some multiple-input multiple-output (MIMO) embodiments, the antennas may be effectively separated for spatial diversity and the different channel characteristics that may result between each of the antennas and the antennas of a transmitting station.

Although the smart wire hardware 300 is illustrated as having several separate functional elements, two or more of the functional elements may be combined and may be implemented by combinations of software-configured elements, such as processing elements including digital signal processors (DSPs), and/or other hardware elements. For example, some elements may include one or more microprocessors, DSPs, field-programmable gate arrays (FPGAs), application specific integrated circuits (ASICs), radio-frequency integrated circuits (RFICs) and combinations of various hardware and logic circuitry for performing at least the functions described herein. In some embodiments, the functional elements of the smart wire hardware 300 may refer to one or more processes operating on one or more processing elements.

Certain embodiments may be implemented in one or a combination of hardware, firmware, and software. Other embodiments may also be implemented as instructions stored on a computer-readable storage device, which may be read and executed by at least one processor to perform the operations described herein. A computer-readable storage device may include any non-transitory memory mechanism for storing information in a form readable by a machine (e.g., a computer).

The word “exemplary” is used herein to mean “serving as an example, instance, or illustration.” Any embodiment described herein as “exemplary” is not necessarily to be construed as preferred or advantageous over other embodiments. The terms “computing device,” “user device,” “communication station,” “station,” “handheld device,” “mobile device,” “wireless device” and “user equipment” (UE) as used herein refers to a wireless communication device such as a cellular telephone, a smartphone, a tablet, a netbook, a wireless terminal, a laptop computer, a femtocell, a high data rate (HDR) subscriber station, an access point, a printer, a point of sale device, an access terminal, or other personal communication system (PCS) device. The device may be either mobile or stationary.

As used within this document, the term “communicate” is intended to include transmitting, or receiving, or both transmitting and receiving. This may be particularly useful in claims when describing the organization of data that is being transmitted by one device and received by another, but only the functionality of one of those devices is required to infringe the claim. Similarly, the bidirectional exchange of data between two devices (both devices transmit and receive during the exchange) may be described as “communicating,” when only the functionality of one of those devices is being claimed. The term “communicating” as used herein with respect to a wireless communication signal includes transmitting the wireless communication signal and/or receiving the wireless communication signal. For example, a wireless communication unit, which is capable of communicating a wireless communication signal, may include a wireless transmitter to transmit the wireless communication signal to at least one other wireless communication unit, and/or a wireless communication receiver to receive the wireless communication signal from at least one other wireless communication unit.

As used herein, unless otherwise specified, the use of the ordinal adjectives “first,” “second,” “third,” etc., to describe a common object, merely indicates that different instances of like objects are being referred to and are not intended to imply that the objects so described must be in a given sequence, either temporally, spatially, in ranking, or in any other manner.

The term “access point” (AP) as used herein may be a fixed station. An access point may also be referred to as an access node, a base station, an evolved node B (eNodeB), or some other similar terminology known in the art. An access terminal may also be called a mobile station, user equipment (UE), a wireless communication device, or some other similar terminology known in the art. Embodiments disclosed herein generally pertain to wireless networks. Some embodiments may relate to wireless networks that operate in accordance with one of the IEEE 802.11 standards.

Some embodiments may be used in conjunction with various devices and systems, for example, a personal computer (PC), a desktop computer, a mobile computer, a laptop computer, a notebook computer, a tablet computer, a server computer, a handheld computer, a handheld device, a personal digital assistant (PDA) device, a handheld PDA device, an on-board device, an off-board device, a hybrid device, a vehicular device, a non-vehicular device, a mobile or portable device, a consumer device, a non-mobile or non-portable device, a wireless communication station, a wireless communication device, a wireless access point (AP), a wired or wireless router, a wired or wireless modem, a video device, an audio device, an audio-video (A/V) device, a wired or wireless network, a wireless area network, a wireless video area network (WVAN), a local area network (LAN), a wireless LAN (WLAN), a personal area network (PAN), a wireless PAN (WPAN), and the like.

Some embodiments may be used in conjunction with one way and/or two-way radio communication systems, cellular radio-telephone communication systems, a mobile phone, a cellular telephone, a wireless telephone, a personal communication system (PCS) device, a PDA device which incorporates a wireless communication device, a mobile or portable global positioning system (GPS) device, a device which incorporates a GPS receiver or transceiver or chip, a device which incorporates an RFID element or chip, a multiple input multiple output (MIMO) transceiver or device, a single input multiple output (SIMO) transceiver or device, a multiple input single output (MISO) transceiver or device, a device having one or more internal antennas and/or external antennas, digital video broadcast (DVB) devices or systems, multi-standard radio devices or systems, a wired or wireless handheld device, e.g., a smartphone, a wireless application protocol (WAP) device, or the like.

Some embodiments may be used in conjunction with one or more types of wireless communication signals and/or systems following one or more wireless communication protocols, for example, radio frequency (RF), infrared (IR), frequency-division multiplexing (FDM), orthogonal FDM (OFDM), time-division multiplexing (TDM), time-division multiple access (TDMA), extended TDMA (E-TDMA), general packet radio service (GPRS), extended GPRS, code-division multiple access (CDMA), wideband CDMA (WCDMA), CDMA 2000, single-carrier CDMA, multi-carrier CDMA, multi-carrier modulation (MDM), discrete multi-tone (DMT), Bluetooth®, global positioning system (GPS), Wi-Fi, Wi-Max, ZigBee, ultra-wideband (UWB), global system for mobile communications (GSM), 2G, 2.5G, 3G, 3.5G, 4G, fifth generation (5G) mobile networks, 3GPP, long term evolution (LTE), LTE advanced, enhanced data rates for GSM Evolution (EDGE), or the like. Other embodiments may be used in various other devices, systems, and/or networks.

The foregoing description of one or more implementations provides illustration and description, but is not intended to be exhaustive or to limit the scope of embodiments to the precise form disclosed. Modifications and variations are possible in light of the above teachings or may be acquired from practice of various embodiments.

Accordingly, blocks of the block diagrams and flow diagrams support combinations of means for performing the specified functions, combinations of elements or steps for performing the specified functions and program instruction means for performing the specified functions. It will also be understood that each block of the block diagrams and flow diagrams, and combinations of blocks in the block diagrams and flow diagrams, may be implemented by special-purpose, hardware-based computer systems that perform the specified functions, elements or steps, or combinations of special-purpose hardware and computer instructions.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language is not generally intended to imply that features, elements, and/or operations are in any way required for one or more implementations or that one or more implementations necessarily include logic for deciding, with or without user input or prompting, whether these features, elements, and/or operations are included or are to be performed in any particular implementation.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims. Although specific terms are employed herein, they are used in a generic and descriptive sense only and not for purposes of limitation.

What is claimed is:

1. A smart wire, comprising:
one or more sensors configured to detect whether the smart wire is connected to or disconnected from a device or port; and
communications circuitry configured to wirelessly communicate data, to a management network, indicative of whether the smart wire is connected to or disconnected from the device or port,
wherein the management network is unassociated with a service using the smart wire and the device or port.

2. The smart wire of claim 1, further comprising:
a first insert arranged at a first end of the smart wire; and
a second insert arranged at a second end of the smart wire,
wherein at least one of the first insert or the second insert comprises the one or more sensors and the communications circuitry.

3. The smart wire of claim 2, wherein the smart wire connects to the device or port via the first insert.

4. The smart wire of claim 2, wherein at least one of the first insert or the second insert comprises a battery.

5. The smart wire of claim 1, wherein the one or more sensors and the communications circuitry are configured to receive traffic of the smart wire by splitting or emitting the traffic from the smart wire.

6. The smart wire of claim 1, wherein the smart wire is an Ethernet cable.

7. The smart wire of claim 6, wherein the one or more sensors are voltage or current sensors.

8. The smart wire of claim 1, wherein the smart wire is a fiber optic.

9. The smart wire of claim 8, wherein the one or more sensors are optical sensors.

10. The smart wire of claim 1, wherein the smart wire is a management wire.

11. The smart wire of claim 1, wherein the communications circuitry is configured to transmit the data to the management network while the smart wire is disconnected from the device or port.

12. A smart wire, comprising:
one or more sensors configured to detect a status of the smart wire; and
communications circuitry configured to wirelessly communicate data indicative of the status to a management network when the smart wire is disconnected,
wherein the management network is unassociated with a service using the smart wire.

13. The smart wire of claim 12, further comprising:
a first insert arranged at a first end of the smart wire; and
a second insert arranged at a second end of the smart wire,
wherein at least one of the first insert or the second insert comprises the one or more sensors and the communications circuitry.

14. The smart wire of claim 13, wherein the smart wire connects to a device or port via the first insert.

15. The smart wire of claim 13, wherein at least one of the first insert or the second insert comprises a battery.

16. The smart wire of claim 12, wherein the one or more sensors and the communications circuitry are configured to receive traffic of the smart wire by splitting or emitting the traffic from the smart wire.

17. The smart wire of claim 12, wherein the smart wire is an Ethernet cable.

18. The smart wire of claim 17, wherein the one or more sensors are voltage or current sensors.

19. The smart wire of claim 12, wherein the smart wire is a fiber optic.

20. The smart wire of claim 19, wherein the one or more sensors are optical sensors.
